(19) United States
(12) Patent Application Publication
(10) Pub. No.: US 2024/0053519 A1
(43) Pub. Date: Feb. 15, 2024

(54) OPTICAL ANGULAR FILTER

(71) Applicant: ISORG, Limoge CEDEX 3 (FR)

(72) Inventors: Jérôme MICHALLON, GRENOBLE (FR); Benjamin BOUTHINON, GRENOBLE (FR)

(21) Appl. No.: 18/266,559

(22) PCT Filed: Nov. 22, 2021
(86) PCT No.: PCT/EP2021/082406

§ 371 Date: Jun. 9, 2023

(30) Foreign Application Priority Data
Dec. 14, 2020 (FR) 20/13145

(51) Int. Cl. G02B 5/20; G02B 3/00; H01L 27/146

(52) U.S. Cl. CPC G02B 5/201; G02B 3/0006; H01L 27/14625; G02B 2207/123

(57) ABSTRACT

An angular filter includes an array of microlenses, a first array of openings in a layer of a first resin and a second array of openings in a layer of a second resin. The first resin blocks at least a first radiation and the second resin blocks a second radiation, different from the first radiation.

### RELATED APPLICATION

The present application is based on and claims priority of French patent application FR2013145 filed on Dec. 14, 2020 and entitled “Filtre angulaire optique”, which is incorporated herein by reference as authorized by law.

### FIELD

The present disclosure concerns an angular optical filter.

More particularly, the present disclosure concerns an angular filter intended to be used within an optical system, for example, an imaging system.

### BACKGROUND

An angular filter is a device enabling to filter an incident radiation according to the incidence of this radiation and thus to block rays having an incidence greater than a maximum incidence. Angular filters are frequently used in association with image sensors.

### SUMMARY OF THE INVENTION

There is a need to improve known angular filters.

An embodiment overcomes all or part of the disadvantages of known angular filters.

An embodiment provides an angular filter comprising an array of microlenses, a first array of openings in a layer of a first resin and a second array of openings in a layer of a second resin, the first resin blocking at least a first radiation and the second resin blocking a second radiation, different from the first radiation.

According to an embodiment, the first radiation corresponds to a radiation having a wavelength in the range from 700 nm to 1,700 nm, preferably in the range from 820 nm to 870 nm or from 910 nm to 970 nm.

According to an embodiment, the second radiation corresponds to a radiation having a wavelength in the range from 400 nm to 600 nm, preferably from 470 nm to 600 nm.

According to an embodiment, the second radiation corresponds to a radiation having a wavelength in the range from 600 nm to 700 nm, preferably from 600 nm to 680 nm.

According to an embodiment, the openings of the first array have, in the direction perpendicular to the axis of the openings, a larger surface area than the openings of the second array, in said direction. This advantageously enables to benefit from a more efficient (stronger) filtering of the second radiation with respect to the first radiation. This is particularly advantageous when the resolution needs in the image are different according to the wavelength. For example, when the object to be imaged in the first wavelength or first radiation (for example, visible+infrared) is relatively large (in which case a lighter filtering is preferable) and the object to be imaged in the second wavelength or second radiation (for example, visible only) is relatively thin (in which case a stronger filtering is preferable).

According to an embodiment, each opening of the first array has its center aligned with an opening of the second array and with the optical axis of a microlens.

According to an embodiment, the angular filter comprises a protection layer between the first array of openings and the second array of openings.

According to an embodiment, the first resin blocks the first radiation.

According to an embodiment, the first resin blocks the second radiation.

According to an embodiment, the openings of the first array are holes, for example, filled with a material transparent to the second radiation and/or to the first radiation.

According to an embodiment, the openings of the second array are holes, for example, filled with a material transparent to the second radiation and/or to the first radiation.

An embodiment provides a manufacturing method comprising the steps of:
a. forming, on a surface of an array of microlenses, a layer of a first resin so that the first resin and the planar surfaces of the microlenses face one another;
b. illuminating with a light radiation the layer of the first resin through the array of microlenses and developing to form a first array of openings in the first resin;
c. forming a layer of a second resin on the first array of openings, on a surface opposite to the microlens array; and
d. illuminating with a light radiation the layer of the second resin through the array of microlenses an developing to form a second array of openings in the second resin, to obtain an angular filter such as described hereabove.

According to an embodiment, the method comprises the steps of:
a. forming, on a surface of an array of microlenses, a layer of a transparent resin so that the transparent resin and the planar surfaces of the microlenses face one another;
b. illuminating with a light radiation the transparent resin layer through the array of microlenses, developing to form a first array of pads in the transparent resin, and filling the spaces between the pads with a first resin;
c. forming another transparent resin layer on the first array, on a surface opposite to the microlens array; and
d. illuminating with a light radiation the other transparent resin layer through the array of microlenses, developing to form a second array of pads in the transparent resin, and filling the spaces between the pads with a second resin, to obtain an angular filter such as described hereabove.

According to an embodiment, the light radiation of step d) is a collimated radiation.

According to an embodiment, the light radiation of step b) is a radiation less collimated than the light radiation of step d).

According to an embodiment, the light radiation is identical and collimated in steps b) and d).

According to an embodiment, the light rays at steps b) and d) are ultraviolet radiations.

According to an embodiment, the method comprises a step e), between step b) and step c), of forming of a protection layer on top of and in contact with the first array.

An embodiment provides an image sensor comprising, at least:
an image sensor formed of an array of photodetectors; and
an angular filter such as described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 illustrates, in a partial and simplified block diagram, an embodiment of an image acquisition system;

FIG. 2 shows, in a partial and simplified cross-section view, an embodiment of an image acquisition device comprising an angular filter;

FIG. 3 shows, in a cross-section view, a step of a method of forming the image acquisition device illustrated in FIG. 2;

FIG. 4 shows, in a cross-section view, another step of a method of forming the image acquisition device illustrated in FIG. 2;

FIG. 5 shows, in a cross-section view, still another step of a method of forming the image acquisition device illustrated in FIG. 2;

FIG. 6 shows, in a cross-section view, still another step of a method of forming the image acquisition device illustrated in FIG. 2;

FIG. 7 shows, in a cross-section view, still another step of a method of forming the image acquisition device illustrated in FIG. 2; and

FIG. 8 shows, in a cross-section view, still another step of a method of forming the image acquisition device illustrated in FIG. 2.

### DESCRIPTION OF THE EMBODIMENTS

Like features have been designated by like references in the various FIGURES. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, only the angular filter is described in the present disclosure, the image sensor as well as the elements forming the processing unit will not be detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made, unless specified otherwise, to the orientation of the FIGURES.

Unless specified otherwise, the expressions “around”, “approximately”, “substantially” and “in the order of” signify within 10%, and preferably within 5%.

Unless specified otherwise, the expressions “all the elements”, “each element”, signify between 95% and 100% of the elements. In the following description, unless specified otherwise, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system transparent to said radiation. In the rest of the disclosure, there is called “useful radiation” the electromagnetic radiation crossing the optical system in operation. In the rest of the disclosure, there is called “micrometer-range optical element” an optical element formed on a surface of a support having a maximum dimension, measured parallel to said surface, greater than 1 μm and smaller than 1 mm.

Embodiments of optical systems will now be described for optical systems comprising an array of micrometer-range optical elements in the case where each micrometer-range optical element corresponds to a micrometer-range lens, or microlens, formed of two diopters. It should however be clear that these embodiments may also be implemented with other types of micrometer-range optical elements, where each micrometer-range optical element may for example correspond to a micrometer-range Fresnel lens, to a micrometer-range index gradient lens, or to a micrometer-range diffraction grating.

In the following description, there is called visible light an electromagnetic radiation having a wavelength in the range from 400 nm to 700 nm, and, in this range, green light an electromagnetic radiation having a wavelength in the range from 400 nm to 600 nm, more preferably from 470 nm to 600 nm. There is called infrared radiation an electromagnetic radiation having a wavelength in the range from 700 nm to 1 mm. In infrared radiation, one can in particular distinguish near infrared radiation having a wavelength in the range from 700 nm to 1.7 μm, more preferably from 850 nm to 940 nm.

FIG. 1 illustrates, in a partial and simplified block diagram, an embodiment of an image acquisition system 11.

Image acquisition system 11, illustrated in FIG. 1, comprises:
an image acquisition device 13 (DEVICE); and
a processing unit 15 (PU).

Processing unit 15 preferably comprises means for processing the signals delivered by device 11, not shown in FIG. 1. Processing unit 15 for example comprises a microprocessor.

Device 13 and processing unit 15 are preferably coupled by a link 17. Device 13 and processing unit 15 are for example integrated in a same circuit.

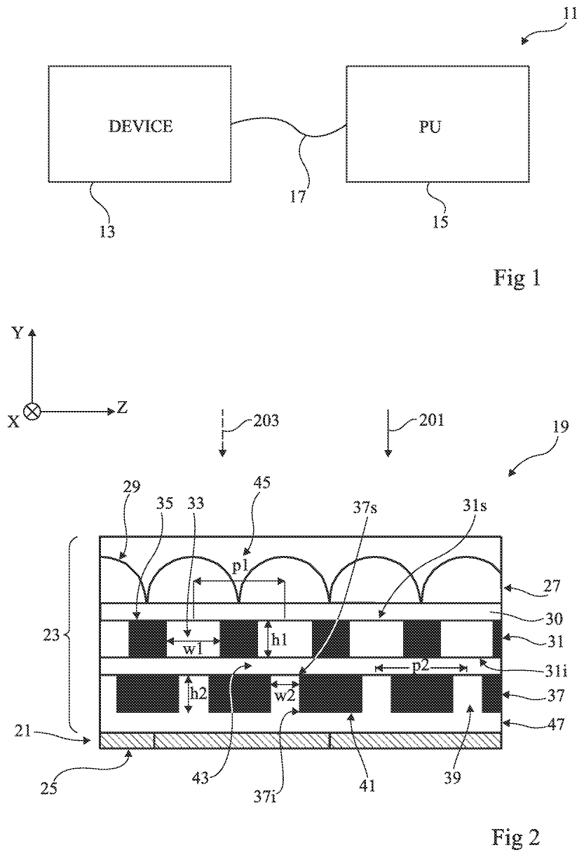

FIG. 2 shows, in a partial simplified cross-section view, an embodiment of an image acquisition device 19 comprising an angular filter.

The image acquisition device 19 shown in FIG. 2 comprises, from bottom to top in the orientation of the drawing:
an image sensor 21; and
an angular filter 23, covering image sensor 21.

In the present disclosure, the embodiments of the devices of FIGS. 2 to 8 are shown in space according to a XYZ direct orthogonal coordinate system XYZ, the Y axis of coordinate system XYZ being orthogonal to the upper surface of image sensor 21.

Image sensor 21 comprises an array of photon sensors 25, also called photodetectors. Photodetectors 25 are preferably arranged in array form. Photodetectors 25 may be covered with a protective coating, not shown.

According to an embodiment, photodetectors 25 all have the same structure and the same properties/characteristics. In other words, all photodetectors 25 are substantially identical, to within manufacturing tolerances.

As a variant, photodetectors 25 do not all have the same characteristics and may be sensitive to different wavelengths. In other words, photodetectors 25 may be sensitive to an infrared radiation and photodetectors 25 may be sensitive to a green radiation.

Image sensor 21 further comprises conductive tracks and switching elements, particularly transistors, not shown, allowing the selection of photodetectors 25.

Photodetectors 25 are preferably made of organic materials. Photodiodes 25 are for example organic photodiodes (OPD) integrated on a CMOS (Complementary Metal Oxide Semiconductor) substrate or a thin film transistor substrate (TFT). The substrate is for example made of silicon, preferably, of single-crystal silicon. The channel, source, and drain regions of the TFT transistors are for example made of amorphous silicon (a-Si), of indium gallium zinc oxide (IGZO), or of low temperature polysilicon (LIPS).

The photodiodes 25 of image sensor 21 comprise, for example, a mixture of organic semiconductor polymers, for example poly(3-hexylthiophene) or poly(3-hexylthiophene-2,5-diyl), known as P3HT, mixed with [6,6]-phenyl-C61-butyric acid methyl ester (N-type semiconductor), known as PCBM.

The photodiodes 25 of image sensor 21 for example comprise small molecules, that is, molecules having molar masses smaller than 500 g/mol, preferably, smaller than 200 g/mol.

Photodiodes 25 may be non-organic photodiodes, for example, formed based on amorphous silicon or crystalline silicon. As an example, photodiodes 25 are formed of quantum dots.

According to an embodiment, each photodetector 25 is adapted to detecting visible radiation and/or near infrared radiation.

Angular filter 23 comprises:
an array 27 of micrometer-range microlenses 29, for example, plano-convex;
a first array 31 or layer of holes or openings 33, for example, filled with a material transparent to a first radiation 203 and/or to a second radiation 201, delimited by walls 35 of a first resin opaque to first radiation 203 and optionally opaque to second radiation 201;
a second array 37 or layer of holes or openings 39, for example, filled with a material transparent to the second 201 and/or to the first radiation 203, delimited by walls 41 of a first resin opaque to second radiation 201.

According to a preferred embodiment, radiation 201 preferably comprises at least one or a plurality of wavelengths in green and/or in blue, that is, one a plurality of wavelengths in the range from 400 nm to 600 nm, preferably in the range from 470 nm to 600 nm. The wavelengths which form radiation 201 are for example all in the range from 400 nm to 600 nm, preferably in the range from 470 nm to 600 nm.

According to an embodiment, radiation 201 preferably comprises at least one or a plurality of wavelengths in red, that is, one or a plurality of wavelengths in the range from 600 nm to 700 nm, preferably in the range from 600 nm to 680 nm. The wavelengths which form radiation 201 are for example all in the range from 600 nm to 700 nm, preferably in the range from 600 nm to 680 nm.

According to an embodiment, radiation 203 preferably comprises one or a plurality of wavelengths in near infrared, that is, one or a plurality of wavelengths in the range from 700 nm to 1,700 nm, preferably in the range from 820 nm to 870 nm and/or from 910 nm to 970 nm. The wavelengths which form radiation 203 are for example all in the range from 700 nm to 1,700 nm, preferably in the range from 820 nm to 870 nm and/or from 910 nm to 970 nm.

According to an embodiment, the array 27 of microlenses 29 is formed on a substrate or support 30 and in contact therewith, substrate 30 then being interposed between microlenses 29 and array 31.

Substrate 30 may be made of a transparent polymer which does not absorb at least the considered wavelengths, here in the visible and near infrared range. The polymer may in particular be polyethylene terephthalate PET, poly(methyl methacrylate) PMMA, cyclic olefin polymer (COP), polyimide (PI), polycarbonate (PC). The thickness of substrate 30 may vary between 1 μm and 100 μm, preferably between 10 μm and 100 μm. Substrate 30 may correspond to a colored filter, to a polarizer, to a half-wave plate or to a quarter-wave plate.

Microlenses 29 may be made of silica, of PMMA, of positive resist, of PET, of poly(ethylene naphthalate) (PEN), of COP, of polydimethylsiloxane (PDMS)/silicone, of epoxy resin, or of acrylate resin. Microlenses 29 may be formed by creeping of resist blocks. Microlenses 29 may further be formed by imprinting on a layer of PET, PEN, COP, PDMS/silicone, of epoxy resin, or of acrylate resin. Microlenses 29 are converging lenses each having a focal distance f in the range from 1 μm to 100 μm, preferably from 1 μm to 70 μm. According to an embodiment, all microlenses 29 are substantially identical.

According to the present embodiment, microlenses 29 and substrate 30 are preferably formed in transparent or partially transparent materials, that is, transparent in a portion of the spectrum considered for the targeted field, for example, imaging, over the wavelength range corresponding to the wavelengths used during the exposure of an object to be imaged.

The planar surfaces of microlenses 29 face openings 33.

According to an embodiment, microlenses 29 are organized in the form of a grid of rows and of columns. Microlenses 29 are for example aligned. The repetition pattern of microlenses 29 is for example a square in which microlenses 29 are located at the four corners of the square.

According to an embodiment, microlenses 29 are organized in the form of a grid of rows and of columns in quincunx. In other words, the repetition pattern of microlenses 29 is for example a square in which microlenses 29 are located at the four corners and at the center of the square.

Call “h1” the thickness of walls 35. Walls 35 are for example opaque to radiation 203 and optionally to radiation 201, for example, absorbing and/or reflective to radiation 203 and optionally to radiation 201.

In the present disclosure, there is called upper surface 31s of layer 31 the surface of layer 31 located at the interface between layer 31 and substrate 30. There is further called lower surface 31i of layer 31 the surface of layer 31 located opposite to upper surface 31s.

In FIG. 2, openings 33 are shown with a square cross-section in the YZ plane. Generally, each opening 33 may have a trapezoidal, rectangular shape or be funnel-shaped. Each opening 33, in top view (that is, in the XZ plane), may have a circular, oval, or polygonal shape, for example, triangular, square, rectangular, or trapezoidal. Each opening 33, in top view, has a preferably circular shape. There is defined by width of an opening 33 the characteristic dimension of opening 33 in the XZ plane. For example, for an opening 33 having a cross-section of square shape in the XZ plane, the width corresponds to the dimension of a side and for an opening 33 having a cross-section of circular shape in the XZ plane, the width corresponds to the diameter of opening 33. Further, there is called center of an opening 33 the point located at the intersection of the axis of symmetry of openings 33 and of the lower surface 31i of layer 31. For example, for circular openings 33, the center of each opening 33 is located on the axis of revolution of opening 33.

According to an embodiment, the openings 33 of layer 31, respectively the openings 39 of layer 37, are organized in the form of a grid of rows and of columns. Openings 33, respectively openings 39, are for example aligned. The repetition pattern of openings 33, respectively of openings 39 is, for example, a square where openings 33, respectively openings 39, are located at the four corners of the square.

According to an embodiment, the openings 33 of layer 31, respectively the openings 39 of layer 37, are organized in the form of a grid of rows and of columns in quincunx. In other words, the repetition pattern of openings 33, respectively of openings 39 is, for example, a square where openings 33, respectively openings 39, are located at the four corners and at the center of the square.

Openings 33 may have all substantially the same dimensions. Call “w1” the width of openings 33 (measured at the base of the openings, that is, at the interface with substrate 30). Call “p1” the repetition pitch of openings 33, that is, the distance, along the X axis or the Z axis, between centers of two successive openings 33 of a row or of a column.

Pitch p1 may be in the range from 5 μm to 50 μm, for example equal to approximately 12 μm. Height h1 may be in the range from 1 μm to 1 mm, preferably in the range from 2 μm to 15 μm. Width w1 is preferably in the range from 0.5 μm to 25 μm, for example, approximately equal to 10 μm.

Each opening 33 is preferably associated with a single microlens 29 of array 27. The optical axes of microlenses 29 are preferably aligned with the centers of the openings 33 of array 31. The diameter of microlenses 29 is preferably greater than the maximum cross-section (measured perpendicularly to the optical axes) of openings 33.

The structure associating the array 27 of microlenses 29 and array 31 is adapted to filtering the incident radiation according to its wavelength and to the incidence of the radiation relative to the optical axes of the microlenses 29 of array 27. In other words, the structure is adapted to filtering incident rays, arriving onto the microlenses, according to their incidences and to their wavelengths.

The structure associating the array 27 of microlenses 29 and array 31 is adapted to blocking rays of first radiation 203 and optionally of second radiation 201, having respective incidences relative to the optical axes of the microlenses 29 of filter 23 greater than a first maximum incidence.

This structure is adapted to only letting through, in the considered wavelength range, rays having an incidence relative to the optical axes of microlenses 29 smaller than the first maximum incidence. For example, the structure only lets through incident rays having an incidence smaller than 15°, preferably smaller than 10°.

Openings 33 are for example filled with air, with a partial vacuum, or with a material at least partially transparent to the first 203 and second 201 radiations.

Layer 31 and layer 37 may optionally be separated by a protection layer 43. Layer 43 covers the lower surface 31i of layer 31. Layer 43 is for example a plastic layer such as a PET, COP, PEN, PI layer, a layer of an epoxy or acrylate resin or an inorganic layer such silicon nitride deposited by a PVD or PECVD technique. Layer 43 for example has a thickness in the range from 0.2 μm to 50 μm, preferably in the order of 2 μm.

Call “h2” the thickness of walls 41. Walls 41 are for example opaque to radiation 201, for example, absorbing and/or reflective to radiation 201.

In the present disclosure, there is called upper surface 37s of layer 37 the surface of layer 37 located at the interface between layer 37 and layer 43. There is further called lower surface 37i of layer 37 the surface of layer 37 located opposite to upper surface 37s.

In FIG. 2, openings 39 are shown with a square cross-section in the YZ plane. Generally, each opening 39 may have a trapezoidal, rectangular shape or be funnel-shaped. Each opening 39, in top view (that is, in the XZ plane), may have a circular, oval, or polygonal shape, for example, triangular, square, rectangular, or trapezoidal. Each opening 39, in top view has, preferably, a shape similar to the shape of an opening 33. There is defined by length of an opening 39 the characteristic dimension of opening 39 in the XZ plane. For example, for an opening 39 having a cross-section of square shape in the XZ plane, the width corresponds to the dimension of a side and for an opening 39 having a cross-section of circular shape in the XZ plane, the width corresponds to the diameter of opening 39. Further, there is called center of an opening 39 the point located at the intersection of the axis of symmetry of openings 39 and of the lower surface 37i of layer 37. For example, for circular openings 39, the center of each opening 39 is located on the axis of revolution of opening 39.

According to an embodiment, openings 39 are arranged in rows and in columns. Openings 39 may have all substantially the same dimensions. Call “w2” the width of openings 39 (measured at the base of the openings, that is, at the interface with substrate 43). Call “p2” the repetition pitch of openings 39, that is, the distance, along the X axis or the Z axis, between centers of two successive openings 39 of a row or of a column.

Pitch p2 is preferably equal to pitch p1 and may thus be in the range from 5 μm to 50 μm, for example equal to approximately 12 μm. Height h2 is for example in the range from 1 μm to 1 mm and preferably in the range from 2 μm to 10 μm. Width w2 is preferably smaller than width w1 and may thus be in the range from 5 μm to 50 μm, for example equal to approximately 6 μm.

Each opening 39 is preferably associated with a single microlens 29 of array 27. The optical axes of microlenses 29 are preferably aligned with the centers of the openings 39 of array 31. The diameter of microlenses 29 is preferably greater than the maximum cross-section (measured perpendicularly to the optical axes) of openings 39.

The structure associating the array 27 of microlenses 29 and array 37 is adapted to filtering the incident radiation according to its wavelength and to the incidence of the radiation relative to the optical axes of the microlenses 29 or array 27. In other words, the structure is adapted to filtering incident rays, arriving onto the microlenses, according to their incidences and to their wavelengths.

The structure associating the array 27 of microlenses 29 and array 37 is adapted to blocking rays of second incident radiation 201 having respective incidences with respect to the optical axes of the microlenses 29 of filter 23 greater than a second maximum incidence, smaller than the first maximum incidence.

This structure is adapted to only letting through, in the considered wavelength range, rays having an incidence relative to the optical axes of microlenses 29 smaller than the second maximum incidence. For example, the structure only lets through incident rays having an incidence smaller than 5°, preferably smaller than 3.5°.

Openings 39 are for example filled with air, with a partial vacuum, or with a material at least partially transparent to the first 203 and second 201 radiations. The filling material of openings 39 forms, preferably, a layer 47 at the lower surface 37i of array 37 to cover walls 41 and planarize said lower surface 37i of array 37.

According to the embodiment illustrated in FIG. 2, each photodetector 25 is associated with four openings 33 (it is for example associated with two openings 33 along the X axis and with two openings 33 along the Z axis) and four openings 39. In practice, the resolution of angular filter 23 may be more than four times greater than the resolution of image sensor 21. In other words, in practice, there may be more than four times more openings 39 (or openings 33) than photodetectors 25.

Microlenses 29 are preferably covered with a planarization layer 45. Layer 45 is made of a material at least partially transparent to the first 203 and second 201 radiations.

As an example, a color filter is deposited at the surface of device 19 or inside thereof, for example, between angular filter 23 and image sensor 21.

An advantage of the present embodiment is that it enables to capture radiation 201 only for incidences smaller than 5°, preferably smaller than 3.5°, and radiation 203 only for incidences smaller than 15°, preferably smaller than 10°. This filtering by incidence and by wavelength enables image sensor 21 to capture images in green or in infrared having optimal resolutions.

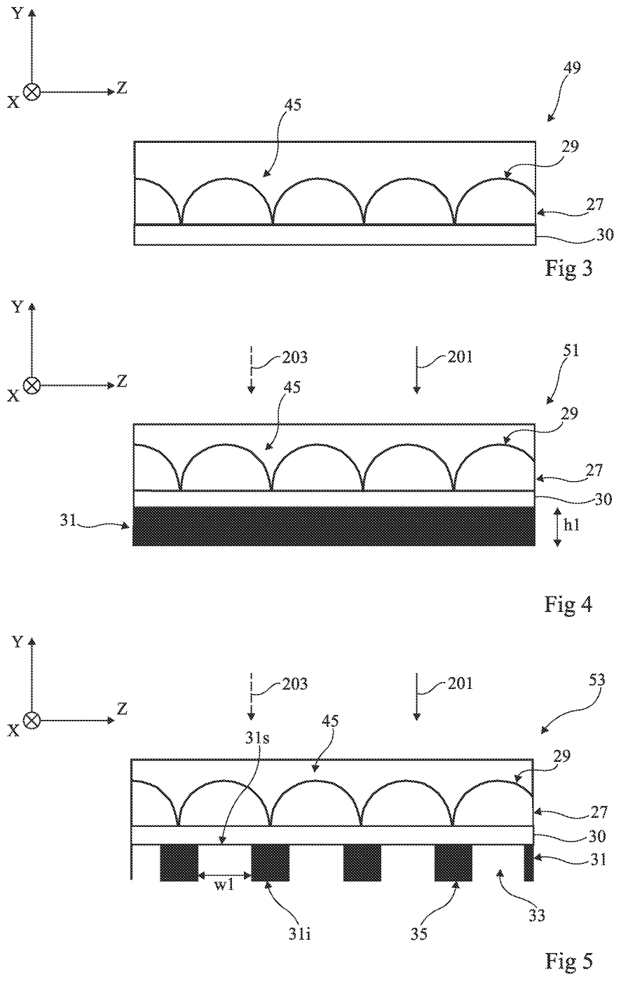

FIG. 3 shows, in a cross-section view, a step of a method of forming the image acquisition device illustrated in FIG. 2.

More particularly, FIG. 3 illustrates a structure 49 comprising the array 27 of microlenses 29 topped, optionally, with layer 45.

FIG. 4 shows, in a cross-section view, another step of a method of forming the image acquisition device illustrated in FIG. 2.

More particularly, FIG. 4 illustrates a structure 51 obtained at the end of a step of deposition of the layer 31 of the first resin onto the lower surface of the structure 49 illustrated in FIG. 3.

Layer 31 made of the first resin, absorbing at least in first radiation 203, is deposited all over the lower surface of structure 49, for example, by a spin coating technique. Layer 31 is deposited over a thickness h1 equivalent to the thickness of the walls 35 formed subsequently.

FIG. 5 shows, in a cross-section view, still another step of a method of forming the image acquisition device illustrated in FIG. 2.

More particularly, FIG. 5 illustrates a structure 53 obtained at the end of a step of illumination of layer 31 of the structure 51 illustrated in FIG. 4.

During this step, layer 31 of structure 51 is illuminated by a radiation, for example, an ultraviolet (UV) radiation. The illumination is performed through the array 27 of microlenses 29, that is, the rays of said radiation cross the array 27 of microlenses 29 before reaching layer 31 on its upper surface 31s. The illumination radiation is non-collimated, that is, the rays of the radiation do not all arrive parallel to one another at the surface of microlenses 29. Each ray of the illumination radiation will thus cross a microlens 29 and come out of it while not necessarily crossing the image focal point of this microlens. The rays will thus cross layer 31 across widths substantially equal to width w1.

After the development, that is, after a rinsing with a developer solution, layer 31 comprises openings 33 delimited by walls 35. Each opening 33 thus has a width w1. The repetition pitch p1 between two openings 33 is equal to the repetition pitch of microlenses 29. At the end of the development step, openings 33 may be filled with a planarization layer, for example, made of PDMS.

As a variant to FIGS. 4 and 5, a layer of resin transparent to radiations 201 and 203 is deposited at the surface of the lower surface of the structure 49 illustrated in FIG. 3, that is, at the surface of the lower surface of substrate 30. The transparent resin layer may then be illuminated with a UV radiation and then developed to form pads similar to the openings 33 illustrated in FIG. 5 when they are filled with a transparent resin. The spaces between two pads are then filled with a material opaque at least to radiation 203 to form walls 35.

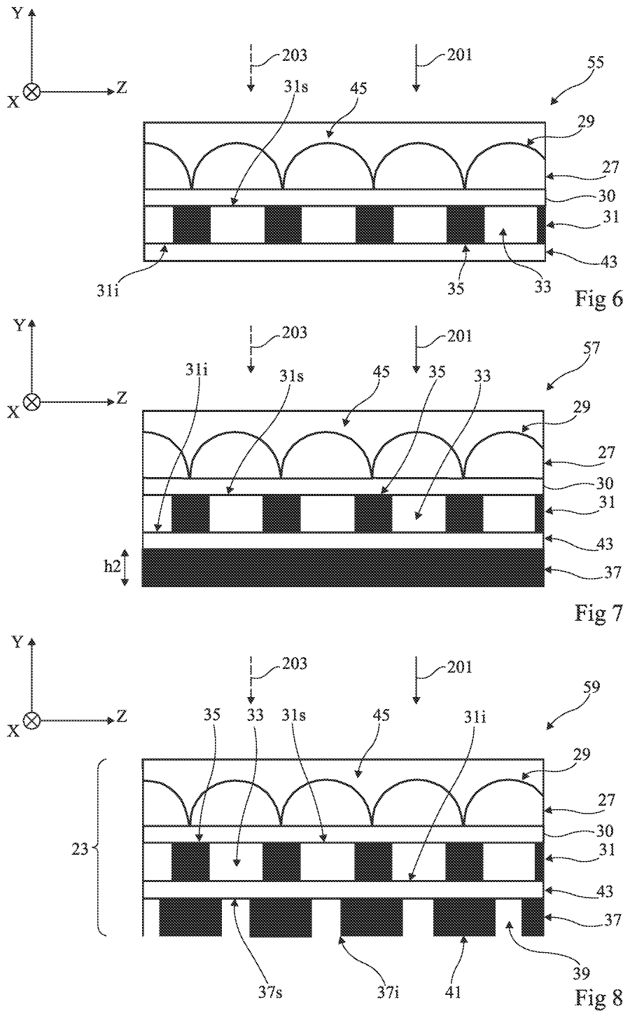

FIG. 6 shows, in a cross-section view, still another step of a method of forming the image acquisition device illustrated in FIG. 2.

More particularly, FIG. 6 illustrates a structure 55 obtained at the end of an optional step of deposition of layer 43 onto the lower surface of the structure 53 illustrated in FIG. 5.

Prior to the step of forming and of deposition of layer 43, the openings 33 of the structure 53 illustrated in FIG. 5 are preferably filled with a transparent material, with air, a gas, or a semi-partial vacuum.

Optional layer 43 is formed by full wafer deposition, for example, by centrifugation, on the lower surface of the structure 53 illustrated in FIG. 5, more precisely on the lower surface 31i of layer 31.

FIG. 7 shows, in a cross-section view, still another step of a method of forming the image acquisition device illustrated in FIG. 2.

More particularly, FIG. 7 illustrates a structure 57 obtained at the end of a step of deposition of the layer 37 of the second resin onto the lower surface of the structure 55 illustrated in FIG. 6.

First resin layer 37, absorbing at least in second radiation 201 but not absorbing in first radiation 203, is deposited all over the lower surface of structure 55, for example, by a spin coating technique. Layer 37 is deposited over a thickness h2 equivalent to the thickness of the walls 41 formed subsequently.

FIG. 8 shows, in a cross-section view, still another step of a method of forming the image acquisition device illustrated in FIG. 2.

More particularly, FIG. 8 illustrates a structure 59 obtained at the end of a step of illumination of the layer 37 of the structure 57 illustrated in FIG. 7.

During this step, the layer 37 of structure 57 is illuminated by a radiation, for example, an ultraviolet (UV) radiation. The illumination is performed through the array 27 of microlenses 29, that is, the rays of said radiation cross the array 27 of microlenses 29 before reaching layer 37 by on upper surface 37s. The illumination radiation is collimated, that is, the rays of the radiation all arrive parallel to one another at the surface of microlenses 29. Each ray of the illumination radiation will thus cross a microlens 29 and come out of it while passing through the image focal point of this microlens located, preferably, in the vicinity of the lower surface of layer 37, that is, the surface of layer 37 opposite to layer 43.

After the development, that is, after a rinsing with a developer solution, layer 37 comprises openings 39 delimited by walls 41. Each opening 39 thus has a width w2. The repetition pitch p1 between two openings 39 is equal to the repetition pitch of microlenses 29.

The difference between width w1 and width w2 originates from the fact that the respective openings are formed with radiations having a different collimation. Indeed, on the one hand openings 33 are formed by means of a slightly diverging radiation, thus having a greater extension as it comes out of microlenses 29, and on the other hand openings 39 are formed by means of a collimated radiation, thus having a smaller extension as it comes out of microlenses 29.

As a variant, the difference between width w1 and width w2 originates from the fact that the respective openings are formed with the same microlenses 29. Indeed, the distance between the image focal points of microlenses 29 and layer 31 is larger than the distance between the image focal points of microlenses 29 and of layer 37. Thus, the width of the radiation cone of each microlens 29 crossing layer 31 will be greater than the width of the same radiation cone crossing layer 37, the width of the radiation cone being substantially null at the image focal point of this same microlens 29.

Similarly to layer 31, layer 37 may as a variant be formed by the deposition of a layer of resin transparent to radiations 201 and 203 at the surface of the lower side of the structure 55 illustrated in FIG. 6, that is, at the surface of the lower side of layer 43. The transparent resin layer may then be illuminated by a UV radiation and then developed to form pads similar to the openings 39 illustrated in FIG. 8 when they are filled with a transparent resin. The spaces between two pads are then filled with a material opaque to radiation 201 to form walls 41.

An advantage of the described embodiments and implementations modes is that they enable to filter at the same time angularly, but also according to the wavelengths, the incident radiation.

Various embodiments and variants have been described. Those skilled in the art will understand that certain features of these various embodiments and variants may be combined, and other variants will occur to those skilled in the art. In particular, a structure comprising a third layer of openings made of a third opaque resin in another optical domain or a structure comprising three layers of openings made of a third resin, could have been envisaged, the three resins being opaque in different optical domains.

Finally, the practical implementation of the described embodiments and variations is within the abilities of those skilled in the art based on the functional indications given hereabove.

1. An angular filter comprising:
an array of microlenses, a first array of openings in a layer of a first resin and a second array of openings in a layer of a second resin, the first resin blocking at least a first radiation and the second resin blocking a second radiation, different from the first radiation,
wherein the first array is arranged between the array of microlenses and the second array,
and wherein the openings of the first array have, in the direction perpendicular to the axis of the openings, a larger surface area than the openings of the second array, in said direction.

2. The angular filter according to claim 1, wherein the first radiation corresponds to a radiation having a wavelength in the range from 700 nm to 1,700 nm, preferably in the range from 820 nm to 870 nm or from 910 nm to 970 nm.

3. The angular filter according to claim 1, wherein the second radiation corresponds to a radiation having a wavelength in the range from 400 nm to 600 nm, preferably from 470 nm to 600 nm.

4. The angular filter according to claim 1, wherein the second radiation corresponds to a radiation having a wavelength in the range from 600 nm to 700 nm, preferably from 600 nm to 680 nm.

5. The angular filter according to claim 1, wherein each opening of the first array has its center aligned with an opening of the second array and with the optical axis of a microlens.

6. The angular filter according to claim 1, comprising a protection layer 434 between the first array of openings and the second array of openings.

7. The angular filter according to claim 1, wherein the first resin blocks the first radiation.

8. The angular filter according to claim 7, wherein the first resin blocks the second radiation.

9. The angular filter according to claim 1, wherein the openings of the first array are holes, for example, filled with a material transparent to the second radiation and/or to the first radiation.

10. The angular filter according to claim 1, wherein the openings of the second array are holes, for example, filled with a material transparent to the second radiation and/or to the first radiation.

11. A manufacturing method to obtain an angular filter according to claim 1, the method comprising the steps of:
a. forming, on a surface of an array of microlenses, a layer of a first resin so that the first resin and the planar surfaces of the microlenses face one another;
b. illuminating with a light radiation the layer of the first resin through the array of microlenses a developing to form a first array of openings in the first resin;
c. forming a layer of a second resin on the first array of openings, on a surface opposite to the microlens array; and
d. illuminating with a light radiation the layer of the second resin through the array of microlenses a developing to form a second array of openings in the second resin.

12. A manufacturing method to obtain an angular filter according to claim 1, the method comprising the steps of:
a. forming, on a surface of an array of microlenses, a layer of a transparent resin so that the transparent resin and the planar surfaces of the microlenses face one another;
b. illuminating with a light radiation the transparent resin layer through the array of microlenses, developing to form a first array of pads in the transparent resin, and filling the spaces between the pads with a first resin;
c. forming another transparent resin layer on the first array, on a surface opposite to the microlens array; and
d. illuminating with a light radiation the other transparent resin layer through the array of microlenses, developing to form a second array of pads in the transparent resin, and filling the spaces between the pads with a second resin.

13. The method according to claim 11, wherein the light radiation of step d) is a collimated radiation.

14. The method according to claim 11, wherein the light radiation of step b) is a radiation less collimated than the light radiation of step d).

15. The method according to claim 11, wherein the light radiation is identical and collimated in steps b) and d).

16. The method according to claim 11, wherein the light radiations at steps b) and d) are ultraviolet radiations.

17. The method according to claim 11, comprising a step e), between step b) and step c), of forming of a protection layer on top of and in contact with the first array.

18. An image sensor comprising, at least:
an image sensor formed of an array of photodetectors; and
an angular filter according to claim 1.
